(19) United States
(12) Patent Application Publication
(10) Pub. No.: US 2013/0146888 A1
(43) Pub. Date: Jun. 13, 2013

(54) MONOLITHIC SEMICONDUCTOR DEVICE AND METHOD FOR MANUFACTURING THE SAME

(71) Applicants: Young Hwan Park, Seoul (KR); Woo Chul Jeon, Gyunggi-do (KR); Ki Yeol Park, Gyunggi-do (KR); Seok Yoon Hong, Gyunggi-do (KR)

(72) Inventors: Young Hwan Park, Seoul (KR); Woo Chul Jeon, Gyunggi-do (KR); Ki Yeol Park, Gyunggi-do (KR); Seok Yoon Hong, Gyunggi-do (KR)

(73) Assignee: SAMSUNG ELECTRO-MECHANICS CO., LTD., Gyunggi-do (KR)

(21) Appl. No.: 13/402,692

(22) Filed: Feb. 22, 2012

(30) Foreign Application Priority Data
Dec. 7, 2011 (KR) 1020110130416

(51) Int. Cl. H01L 29/10

(52) U.S. Cl. 257/76; 257/195; 257/E29.06

(57) ABSTRACT

Disclosed herein is a monolithic semiconductor device including: a substrate; a high electron mobility transistor (HEMT) structure that is a first device structure formed on the substrate; and a laterally diffused metal oxide field effect transistor (LDMOSFET) structure that is a second device structure formed to be connected with the HEMT structure on the substrate.The monolithic semiconductor device according to preferred embodiments of the present invention is a device having characteristics of a normally-off device while maintaining high current characteristics in a normally-on state, thereby improving high current and high voltage operation characteristics.

### CROSS REFERENCE TO RELATED APPLICATION

This application claims the benefit of Korean Patent Application No. 10-2011-0130416, filed on Dec. 7, 2011, entitled “Monolithic Semiconductor Device And Method For Manufacturing The Same”, which is hereby incorporated by reference in its entirety into this application.

### BACKGROUND OF THE INVENTION

1. Technical Field

The present invention relates to a monolithic semiconductor device and a method for manufacturing the same.

2. Description of the Related Art

The interest in power consumption reduction has been increased due to a green energy policy, or the like. To this end, it is essential to increase power conversion efficiency. Upon the power conversion, efficiency of a power switching device depends on the overall power conversion efficiency. As a power device used for the prior art, a power MOSFET or an IGBT using silicon has been mainly used. However, there is a limitation in increasing efficiency of the power device due to a limitation in physical properties of silicon.

To resolve the above problem, as described in Korean Patent Laid-Open Publication No. 2007-0092482 (Laid-Open Publication Date: Sep. 13, 2007), research into increasing conversion efficiency by manufacturing a nitride-based field effect transistor based on nitride such as GaN has been conducted.

The nitride-based field effect transistor has a so-called high electron mobility transistor (hereinafter, referred to as ‘HEMT’) structure.

For example, a semiconductor device having the above HEMT structure includes a base substrate, a nitride-based semiconductor layer formed on the base substrate, a source electrode and a drain electrode disposed on the semiconductor layer, and a gate electrode disposed on the semiconductor layer between the source electrode and the drain electrode, as described in Korean Patent Laid-Open No. 2007-0092482 (Publication in Sep. 13, 2007). The above-mentioned semiconductor device may generate a 2-dimensional electron gas (2DEG) used as a moving path of current therein.

However, the nitride-based field effect transistor having the above-mentioned structure applies negative (−) voltage to the gate electrode so as to maintain an off state, but may generate current and power consumption in the off state and degrade high voltage and high current operation characteristics of the device.

To improve the problem, a technology of a normally on structure applying negative voltage to the gate or a normally-off structure turning-off a switch when gate voltage is 0V has been known. However, the normally-off structure has current density and withstand voltage lower than the normally on structure and cannot be easily manufactured due to a complicated structure.

### SUMMARY OF THE INVENTION

The present invention has been made in an effort to provide a monolithic semiconductor device capable of being operated at high voltage and high current by forming a HEMT and an LDMOSFET having a normally on structure made of nitride on the same substrate.

Further, the present invention has been made in an effort to provide a method for manufacturing a monolithic semiconductor device capable of achieving the above object.

According to a preferred embodiment of the present invention, there is provided a monolithic semiconductor device, including: a substrate; a first device structure formed on the substrate; and a second device structure formed on the substrate while being connected with the first structure.

The first device structure may be a high electron mobility transistor (HEMT) structure and the second device structure is a laterally diffused metal oxide field effect transistor (LDMOSFET) structure.

A common electrode may be formed by integrally connecting a source of the HEMT structure and a drain of the LDMOSFET structure with each other.

The HEMT structure may have a structure in which a nitride semiconductor layer having a lower layer and an upper layer sequentially stacked thereon is formed on the substrate and a source, a drain, and a gate are formed on the upper layer thereof, the upper layer being made of nitride having an energy band gap wider than that of the lower layer.

The gate of the HEMT structure and the source of the LDMOSFET structure may be connected with each other by any one of a connection wiring, a wire, and a lead frame at the outside or may be connected with each other, having a fine circuit board as an intermediate medium disposed therebetween.

An end of the upper layer may be provided with an isolation so as to block leakage current through the source of the HEMT structure and increase withstand voltage of the HEMT structure.

According to another preferred embodiment of the present invention, there is provided a method for manufacturing a monolithic semiconductor device, including: forming on a substrate a nitride semiconductor layer exposing an LDMOSFET structure region and having a lower layer and an upper layer sequentially stacked thereon in a HEMT structure region; forming a drift region and a plurality of well regions by implanting an n-type dopant and a p-type dopant into the LDMOSFET structure region; forming sources and drains ohmic-contacting each other in the HEMT structure region and the LDMOSFET structure region, respectively; and forming gates in the HEMT structure region and the LDMOSFET structure region, respectively.

The forming of the nitride semiconductor layer may include: forming the nitride semiconductor layer over a top surface of the substrate; forming a photo resist pattern covering the HEMT structure region on the upper layer; and etching and removing the nitride semiconductor layer corresponding to the LDMOSFET structure region by a lithography method using the photoresist pattern.

The forming of the nitride semiconductor layer may include: forming a nitride antigrowth film pattern covering the LDMOSFET structure region and exposing the HEMT structure region over the substrate; sequentially forming the nitride semiconductor layers in the HEMT structure region exposed by using the nitride antigrowth film pattern; and etching and removing the nitride antigrowth film pattern.

The forming of the source and the drain may further include forming a common electrode formed by integrally connecting the source of the HEMT structure and the drain of the LDMOSFET structure with each other.

The forming of the gate may further include connecting the gate of the HEMT structure and the source of the LDMOSFET structure with each other by any one of a connection wiring, a wire, and a lead frame at the outside.

The forming of the isolation may perform in-situ on the forming of the drift region and the plurality of well regions.

### BRIEF DESCRIPTION OF THE DRAWINGS

FIG. 1 is a cross-sectional view of a monolithic semiconductor device according to a preferred embodiment of the present invention.

FIG. 2 is a plan view of the monolithic semiconductor device according to the preferred embodiment of the present invention.

FIGS. 3 to 7 are cross-sectional views sequentially showing a manufacturing process of the monolithic semiconductor device according to the preferred embodiment of the present invention.

### DESCRIPTION OF THE PREFERRED EMBODIMENTS

Various features and advantages of the present invention will be more obvious from the following description with reference to the accompanying drawings.

The above and other objects, features and advantages of the present invention will be more clearly understood from preferred embodiments and the following detailed description taken in conjunction with the accompanying drawings. In the specification, in adding reference numerals to components throughout the drawings, it is to be noted that like reference.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. In the description, the terms “first”, “second”, and so on are used to distinguish one element from another element, and the elements are not defined by the above terms. In describing the present invention, a detailed description of related known functions or configurations will be omitted so as not to obscure the gist of the present invention.

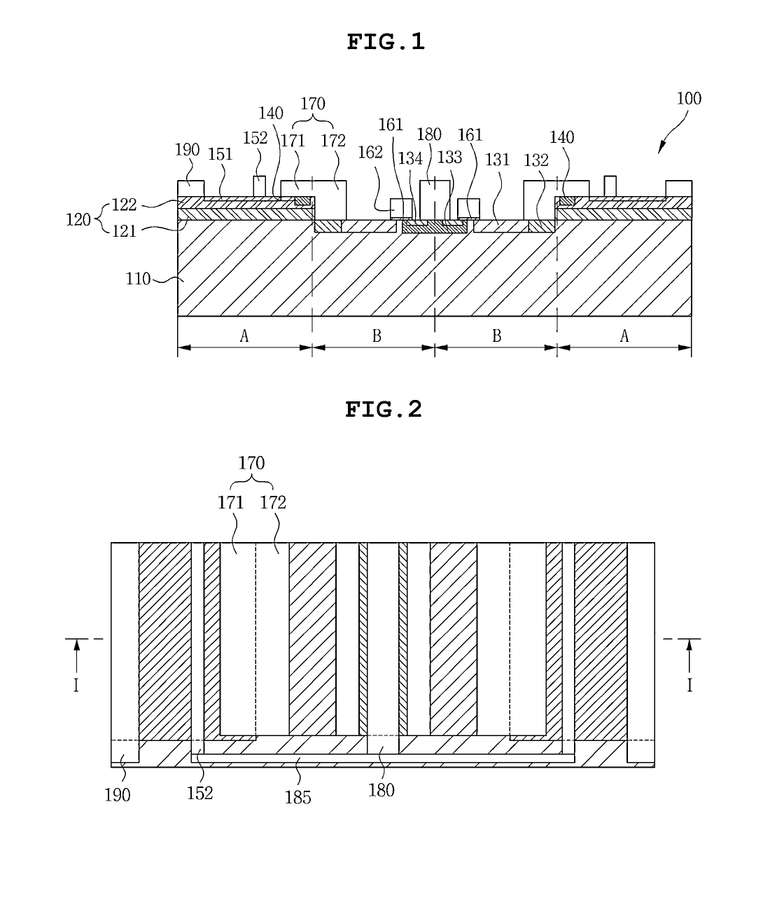

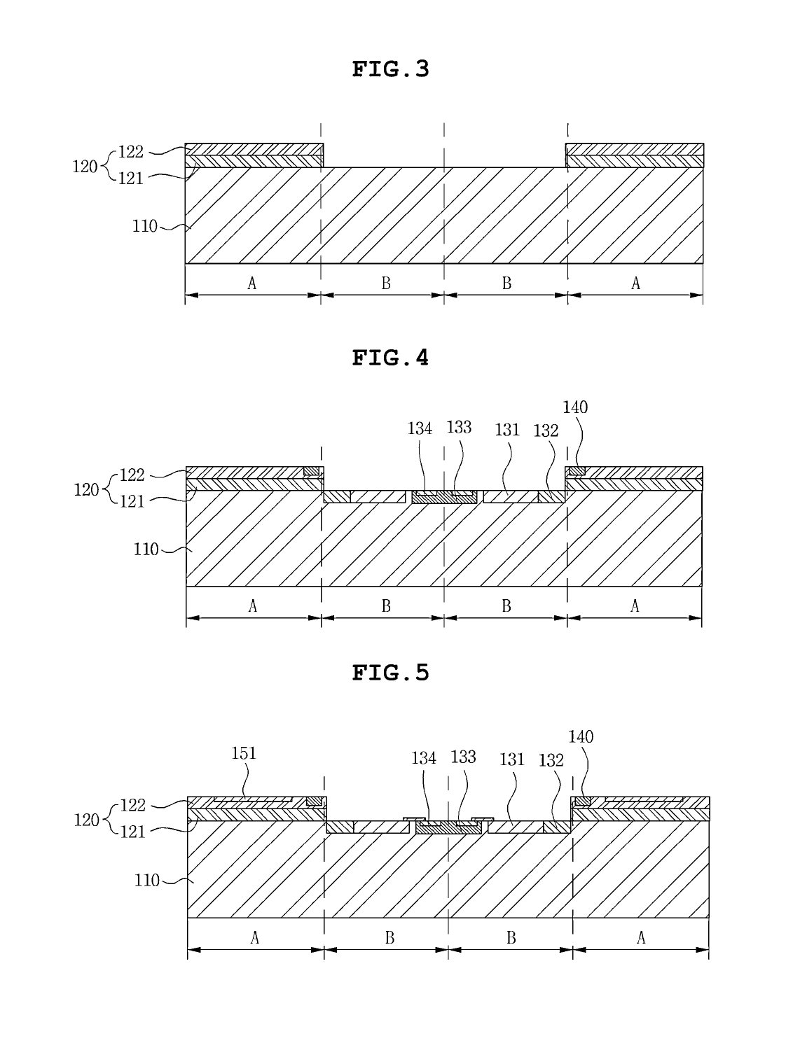

Hereinafter, preferred embodiments of the present invention will be described in detail with reference to the accompanying drawings. FIG. 1 is a cross-sectional view of a monolithic semiconductor device according to a preferred embodiment of the present invention and FIG. 2 is a plan view of the monolithic semiconductor device according to the preferred embodiment of the present invention. The monolithic semiconductor device according to the preferred embodiment of the present invention has a shape in which a first device structure and a second device structure having different functions are formed on the same substrate.

As shown in FIG. 1, a monolithic semiconductor device 100 according to the preferred embodiment of the present invention has a monolithic shape in which a region A implementing a high electron mobility transistor (HEMT) structure performing a depletion mode operation that is a first structure and a region (B) implementing a laterally diffused metal oxide field effect transistor (LDMOSFET) structure that is a second structure connected with the HEMT structure to perform a normally-off operation are formed on the same substrate 110.

As the substrate 110, for example, a silicon substrate, a silicon carbide substrate, or the like, may be used so as to provide the HEMT region A and the LDMOSFET region B.

The HEMT region A is a region in which the first structure, that is, the HEMT structure is implemented and has a structure in which a nitride semiconductor layer 120 on which a lower layer 121 and an upper layer 122 are sequentially stacked is formed on the substrate 110 and a source 171, a drain 190, and a gate 152 are formed on the upper layer 122 thereof Further, a gate insulating layer 151 may selectively be provided under the gate 152.

In this configuration, the upper layer 122 may be made of a material having an energy band gap wider than that of the lower layer 121. For example, the lower layer 121 and the upper layer 122 may be made of III-nitride based materials. In more detail, the lower layer 121 and the upper layer 122 may each be made of any one of GaN, AlGaN, InGaN, and InAlGaN.

In this case, the HEMT region A shown in FIG. 1 has a structure in which the nitride semiconductor layer 120 on which the lower layer 121 made of GaN and the upper layer 122 made of AlGaN are stacked is formed and the source 171, the drain 172, and the gate 152 are formed on the upper layer 122 made of AlGaN.

The LDMOSFET region B is a region in which the second structure, the LDMOSFET structure is implemented and is a region in which the LDMOSFET adjusted to switch the HEMT of the HEMT region A to an on or off state according to applied voltage. The LDMOSFET, which has rapid switching response and high input impedance characteristics, is a power device that can be operated at high power by increasing breakdown voltage.

The LDMOSFET structure has a structure in which a source 180, a drain 172, and a gate 162 are formed on an upper surface of the substrate 110 on which a drift region 131, n⁺ well regions 132 and 134, a p well region 133, or the like, are formed.

In this case, as shown in FIG. 2, the common electrode 170 is formed by integrally connecting the source 171 of the HEMT region A and the drain 172 of the LDMOSFET region B with each other. The common electrode 170 may be used as a drain electrode in the LDMOSFET region B while being used as a source electrode in the HEMT region A.

In addition, the gate 152 of the HEMT region A and the source 180 of the LDMOSFET region B may be connected with each other at the outside by a connection wiring 185. In this case, the gate 152 of the HEMT region A and the source 180 of the LDMOSFET region B may be connected with each other by, for example, a wire, a lead frame, or the like, in addition to the connection wiring 185 or may be connected with each other, having a fine circuit board as an intermediate medium disposed therebetween.

One side under the source 171 of the HEMT region A, that is, an end of the upper layer 122 made of AlGaN may be formed with an isolation 140 that blocks leakage current through the source 171 of the HEMT region A and increases the withstand voltage of the HEMT region A. In this case, the isolation 140 may be a region made of oxides or nitrides such as SiO2, SiN, or the like or a doping region formed by implanting inert elements such as Ar, N, or the like, into the end of the upper layer 122 made of AlGaN.

In the monolithic semiconductor device 100 according to the preferred embodiment of the present invention configured as described above, the LDMOSFET may be in an ‘on’ state when voltage larger than threshold voltage between the gate 162 and the source 180 of the LDMOSFET region B is applied to the gate 162. In this case, the gate voltage of the HEMT region A may be controlled so as to approach ‘0’ V. Therefore, both of the HEMT and the LDMOSFET may be turned-on.

As a result, the monolithic semiconductor device 100 according to the preferred embodiment of the present invention may use high current characteristics of the HEMT performing the normally-on operation, thereby improving high-current and high-voltage characteristics of the device 100.

On the other hand, in the monolithic semiconductor device 100 according to the preferred embodiment of the present invention, voltage lower than threshold voltage between the gate 162 and the source 180 of the LDMOSFET region B may be applied to the gate 162. For example, when voltage of −20V is applied to the gate 162 of the LDMOSFET region B, the voltage of the gate 152 may be relatively lower than that of the source 171 in the HEMT region A and the voltage of the drain 172 may be increased similar to the breakdown voltage of the LDMOSFET in the LDMOSFET region B.

Therefore, the LDMOSFET region B and the HEMT region A simultaneously maintain an ‘off’ state and most voltage applied to the monolithic semiconductor device 100 is applied to the HEMT region A to show the high voltage characteristics.

Therefore, the monolithic semiconductor device 100 may simultaneously show the characteristics of the normally-off device while maintaining the high current characteristics in the normally on state.

In the monolithic semiconductor device 100 according to the preferred embodiment of the present invention, the HEMT structure performing the normally on operation and the LDMOSFET structure connected to the HEMT structure to perform the normally off operation are formed on the same substrate 110.

Therefore, the monolithic semiconductor device 100 according to the preferred embodiment of the present invention has both of the high current density and withstand voltage characteristics of the HEMT and the normally-off characteristic of the LDMOSFET and increases current amount at the time of a forward operation, thereby improving the operation characteristics for high current and high voltage.

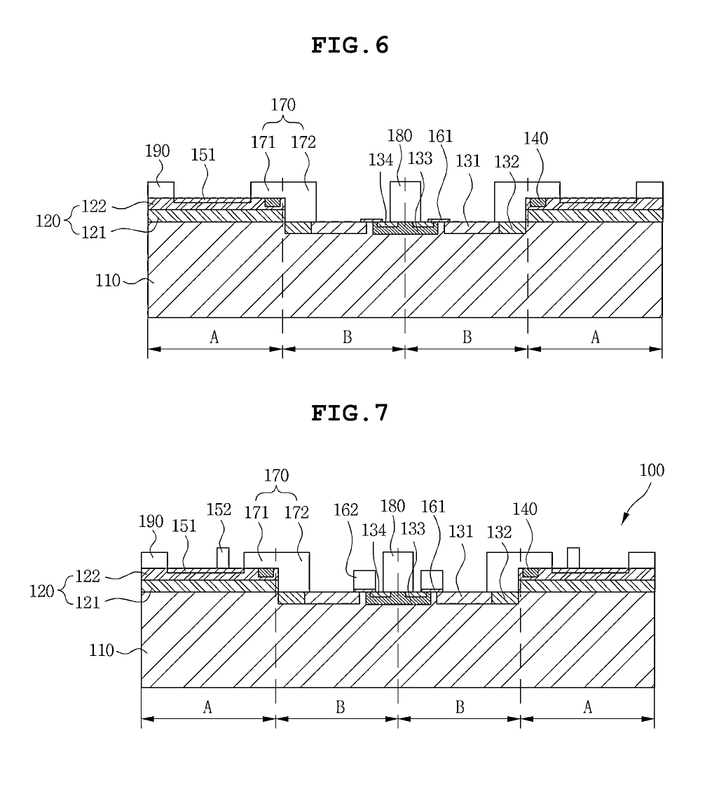

Hereinafter, a method for manufacturing the monolithic semiconductor device 100 according to the preferred embodiment of the present invention will be described with reference to FIGS. 3 to 8. FIGS. 3 to 8 are cross-sectional views sequentially showing a manufacturing process of the monolithic nitride semiconductor device according to the preferred embodiment of the present invention.

First, as shown in FIG. 3, a method for manufacturing the monolithic semiconductor device 100 according to the preferred embodiment of the present invention exposes the LDMOSFET region B on the substrate 110 and forms the nitride semiconductor layer 120 on which the lower layer 121 and the upper layer 122 are sequentially stacked in the HEMT region A.

Here, each of the LDMOSFET regions B may symmetrically be formed at both sides based on a center and each of the HEMT regions A may be formed at the outside while contacting the LDMOSFET region B.

The nitride semiconductor layer 120 is a structure layer formed with a channel through which current flows along an interface between the lower layer 121 and the upper layer 122. Therefore, the upper layer 122 may be made of a material having an energy band gap wider than that of the lower layer 121. For example, the lower layer 121 and the upper layer 122 may each be made of any one of GaN, AlGaN, InGaN, and InAlGaN. As shown in FIG. 3, the nitride semiconductor layer 120 has a shape in which the lower layer 121 is made of GaN and the upper layer 122 is made of AlGaN.

Here, two methods for forming the nitride semiconductor layer 120 in only the HEMT region A of the substrate 110 may be proposed.

A first method forms the nitride semiconductor layer 120 on which the lower layer 121 and the upper layer 122 are stacked is formed over a top surface of the substrate 110, wherein a photo resist pattern (not shown) covering the HEMT region A is formed on the upper layer 122. Thereafter, the nitride semiconductor layer 120 corresponding to the LDMOSFET region B is etched and removed by a lithography method using the photoresist pattern.

Therefore, the top surface of the substrate 110 corresponding to the LDMOSFET region B may be exposed.

A second method forms a nitride antigrowth film pattern (not shown) covering the LDMOSFET region B and exposing the HEMT region A over the substrate 110. Here, the nitride antigrowth film pattern may be made of oxides such as SiO2, or the like.

The HEMT region A exposed using the nitride antigrowth film pattern is formed with the nitride semiconductor layer 120 on which the lower layer 121 and the upper layer 122 are stacked.

Thereafter, the nitride antigrowth film pattern formed in the LDMOSFET region B is etched and removed.

Therefore, the top surface of the substrate 110 corresponding to the LDMOSFET region B may be exposed.

As such, after forming the nitride semiconductor layer 120 in only the HEMT region A on the substrate 110, the drift region 131 and a plurality of well regions 132, 133, and 134 are formed by implanting an n-type dopant and a p-type dopant into the LDMOSFET region B as shown in FIG. 4. Here, the plurality of well regions, which are a well region for forming the LDMOSFET structure, include a first n⁺ well region 132 contacting the drift region 131 under the drain 172, a p well region 133 formed under the source 180, and a second n⁺ well region 134 contacting the gate insulating layer 161 and the source 180 above the p well region 133, or the like.

Here, the drift region 131 is an n-type drift region. Meanwhile, to form the drift region 131, a thermal diffusion process may be additionally performed.

After the drift region 131 and the plurality of well regions 132, 133, and 134 are formed in each of the LDMOSFET regions B, as shown in FIG. 5, the end of the upper layer 122 on which the source 171 of the HEMT structure is formed may be selectively formed with the isolation 140 so as to block the leakage current through the source 171 and increase the withstand voltage of the HEMT region A.

In this case, a process of forming the isolation 140 shown in FIG. 5 may be formed by in-situ, simultaneously with a process of forming the drift region 131 and the plurality of well regions 132, 133, and 134 of the LDMOSFET region B shown in FIG. 4.

Here, the isolation 140 may be a doping region formed by implanting inert elements such as Ar, N, or the like, into the end of the upper layer 122 but is not limited thereto. Therefore, the isolation 140 may also be a region formed by etching the corresponding region and burying oxides or nitrides such as SiO2, SiN, or the like.

In addition, after the isolation 140 is selectively formed, as shown in FIG. 6, the gate insulating layers 151 and 161 formed under the gates 152 and 162 may be selectively formed.

More specifically, the gate insulating layer 151 of the HEMT region A is formed on the upper layer 122 between the source 171 and the drain 190. On the other hand, the gate insulating layer 161 of the LDMOSFET region B may be formed on the substrate 110 while contacting the drift region 131 and the second n⁺ well region 134. The gate insulating layers 151 and 161 may be simultaneously formed by using oxides or nitrides such as Al₂O₃, SiO₂, SN, or the like.

After selectively forming the gate insulating layers 151 and 161, as shown in FIG. 7, the sources 171 and 180 and the drains 172 and 190 that ohmic-contact each other are formed. In this case, the common electrode 170 is formed by integrally connecting the source 171 of the HEMT region A and the drain 172 of the LDMOSFET region B with each other.

A process of forming the sources 171 and 180 and the drains 172 and 190 including the common electrode 170 may be performed so as to ohmic-contact each other, including (i) a metal deposition process using the photoresist pattern exposing the sources 171 and 180 and drains 172 and 190 regions, (ii) a lift-off process removing the photoresist pattern, and (iii) a rapid thermal annealing (RTA) process for the metal pattern of the remaining sources 171 and 180 and drains 172 and 190.

Thereafter, as shown in FIG. 8, the gates 152 and 162 are formed on the gate insulating layers 151 and 161.

More specifically, in order to form the gates 152 and 162 on the gate insulating layers 151 and 161, the photoresist pattern (not shown) exposing the gate 152 and 162 region is first formed on the top surface of the structure shown in FIG. 7. Further, the gates 152 and 162 may be formed without the gate insulating layers 151 and 161.

After the photoresist pattern exposing the gates 152 and 162 region is formed, the gates 152 and 162 may be formed by performing the metal deposition process using the photoresist pattern and the lift-off process removing the photoresist pattern.

In this case, the process of forming the gates 152 and 162 may include the process of forming the connection wiring 185 connecting the gate 152 of the HEMT region A and the source 180 of the LDMOSFET region B with each other at the outside. In this case, the gate 152 of the HEMT region A and the source 180 of the LDMOSFET region B may be connected with each other at the outside by, for example, a wire, a lead frame, or the like, in addition to the connection wiring 185 or may be connected with each other, having a fine circuit board as an intermediate medium disposed therebetween.

The method for manufacturing a monolithic semiconductor device 100 according to the preferred embodiment of the present invention including the above-mentioned processes may easily simultaneously form the region A of the HEMT structure and the region B of the LDMOSFET structure connected with the HEMT structure to perform the normally-off operation on the same substrate 110.

Therefore, the method for manufacturing a monolithic semiconductor device 100 according to the preferred embodiment of the present invention can provide the monolithic semiconductor device that can be operated at high voltage and high current.

The monolithic semiconductor device according to the preferred embodiments of the present invention can improve the high-current and high-voltage operation characteristics by forming the HEMT region performing the normally on operation and the LDMOSFET region connected with the HEMT region to perform the normally-off operation on the same substrate.

The method for manufacturing the monolithic semiconductor device according to the preferred embodiments of the present invention can easily simultaneously form the HEMT region performing the normally on operation and the LDMOSFET region connected with the HEMT region to perform the normally off operation on the same substrate.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A monolithic semiconductor device, comprising:
a substrate;
a first device structure formed on the substrate; and
a second device structure formed on the substrate while being connected with the first structure.

2. The monolithic semiconductor device as set forth in claim 1, wherein the first device structure is a high electron mobility transistor (HEMT) structure and the second device structure is a laterally diffused metal oxide field effect transistor (LDMOSFET) structure.

3. The monolithic semiconductor device as set forth in claim 2, wherein a common electrode is formed by integrally connecting a source of the HEMT structure and a drain of the LDMOSFET structure with each other.

4. The monolithic semiconductor device as set forth in claim 2, wherein the HEMT structure has a structure in which a nitride semiconductor layer having a lower layer and an upper layer sequentially stacked thereon is formed on the substrate and a source, a drain, and a gate are formed on the upper layer thereof, the upper layer being made of nitride having an energy band gap wider than that of the lower layer.

5. The monolithic semiconductor device as set forth in claim 4, wherein the lower layer or the upper layer is made of any one of GaN, AlGaN, InGaN, and InAlGaN.

6. The monolithic semiconductor device as set forth in claim 2, wherein the LDMOSFET structure has a structure in which a source, a drain, and a gate are formed on a top surface of the substrate including at least a drift region and a plurality of well regions.

7. The monolithic semiconductor device as set forth in claim 2, wherein the gate of the HEMT structure and the source of the LDMOSFET structure are connected with each other by any one of a connection wiring, a wire, and a lead frame at the outside or are connected with each other, having a fine circuit board as an intermediate medium disposed therebetween.

8. The monolithic semiconductor device as set forth in claim 2, wherein the HEMT structure performs a depletion mode operation and the LDMOSFET structure is connected with the HEMT structure to perform a normally-off operation.

9. The monolithic semiconductor device as set forth in claim 4, wherein an end of the upper layer is provided with an isolation so as to block leakage current through the source of the HEMT structure and increase withstand voltage of the HEMT structure.

10. The monolithic semiconductor device as set forth in claim 9, wherein the isolation is provided as any one of a region made of oxides, a region made of nitrides, and a doping region into which inert elements are implanted.

11. A method for manufacturing a monolithic semiconductor device, comprising:
forming on a substrate a nitride semiconductor layer exposing an LDMOSFET structure region and having a lower layer and an upper layer sequentially stacked thereon in a HEMT structure region;
forming a drift region and a plurality of well regions by implanting an n-type dopant and/or a p-type dopant into the LDMOSFET structure region;
forming sources and drains ohmic-contacting each other in the HEMT structure region and the LDMOSFET structure region, respectively; and
forming gates in the HEMT structure region and the LDMOSFET structure region, respectively.

12. The method as set forth in claim 11, wherein the gates have gate insulating layers disposed thereunder.

13. The method as set forth in claim 11, wherein at the forming of the nitride semiconductor layer, the upper layer is made of nitrides having an energy band gap wider than that of the lower layer

14. The method as set forth in claim 13, wherein the lower layer or the upper layer is made of any one of GaN, AlGaN, InGaN, and InAlGaN.

15. The method as set forth in claim 11, wherein the forming of the nitride semiconductor layer includes:
forming the nitride semiconductor layer over a top surface of the substrate;
forming a photo resist pattern covering the HEMT structure region on the upper layer; and
etching and removing the nitride semiconductor layer corresponding to the LDMOSFET structure region by a lithography method using the photoresist pattern.

16. The method as set forth in claim 11, wherein the forming of the nitride semiconductor layer includes:
forming a nitride antigrowth film pattern covering the LDMOSFET structure region and exposing the HEMT structure region over the substrate;
sequentially forming the nitride semiconductor layers in the HEMT structure region exposed by using the nitride antigrowth film pattern; and
etching and removing the nitride antigrowth film pattern.

17. The method as set forth in claim 16, wherein the nitride antigrowth film pattern is made of oxides such as SiO₂.

18. The method as set forth in claim 11, wherein the forming of the drift region and the plurality of well regions further selectively includes forming isolation formed of any one of a region made of oxides on the end of the upper layer, a region made of nitrides, and a doping region into which inert elements are implanted.

19. The method as set forth in claim 11, wherein the forming of the source and the drain further includes forming a common electrode formed by integrally connecting the source of the HEMT structure and the drain of the LDMOSFET structure with each other.

20. The method as set forth in claim 11, wherein the forming of the gate further includes connecting the gate of the HEMT structure and the source of the LDMOSFET structure with each other by any one of a connection wiring, a wire, and a lead frame.

21. The method as set forth in claim 18, wherein the forming of the isolation performs in-situ on the forming of the drift region and the plurality of well regions.
